(19) United States
(12) Patent Application Publication
(10) Pub. No.: US 2025/0378863 A1
(43) Pub. Date: Dec. 11, 2025

(54) SEMICONDUCTOR DEVICE HAVING COMMAND SHIFTER CIRCUIT WITH COMMAND BURST POWER SAVE

(71) Applicant: Micron Technology, Inc., Boise, ID (US)

(72) Inventor: Yukimi Morimoto, Sagamihara (JP)

(73) Assignee: Micron Technology, Inc., Boise, ID (US)

(21) Appl. No.: 19/229,929

(22) Filed: Jun. 5, 2025

Related U.S. Application Data
(60) Provisional application No. 63/656,256, filed on Jun. 5, 2024.

(51) Int. Cl. G11C 7/22; G11C 7/10

(52) U.S. Cl. CPC G11C 7/222; G11C 7/1087; G11C 7/109

(57) ABSTRACT

An example apparatus includes an even global command path configured to drive a first even internal command responsive to a first clock signal, an odd global command path configured to drive a first odd internal command responsive to a second clock signal, and a clock control circuit configured to control whether the first clock signal is provided to at least a portion of the even global command path or not based on a first detection signal activated when the second even internal command keeps an active state during a predetermined period of time and control whether the second clock signal is provided to at least a portion of the odd global command path or not based on the second detection signal activated when the second odd internal command keeps an active state during a predetermined period of time.

### CROSS-REFERENCE TO RELATED APPLICATIONS

This application claims the filing benefit of U.S. Provisional Application No. 63/656,256, filed Jun. 5, 2024. This application is incorporated by reference herein in its entirety and for all purposes.

### BACKGROUND

In recent years, the frequency of clock signals used in a semiconductor device such as a DRAM has been increasing significantly. In a DDR5 DRAM, an operation margin at the time of using a high-speed clock signal is secured by, for example, performing latency counting of commands in synchronization with a divided clock signal generated by dividing an external clock signal. When latency counting of commands is performed using a divided clock signal, its latency counting pitch becomes equivalent to two clock cycles of the external clock signal, so that there arises an issue with handling a case where the number of times of counting is an odd number.

### BRIEF DESCRIPTION OF THE DRAWINGS

FIG. 1 is a block diagram showing a configuration of a semiconductor device according to an embodiment of the present disclosure;

FIG. 2 is a waveform diagram showing relations between external clock signals and divided clock signals;

FIG. 3 is a timing diagram for explaining the operation of a semiconductor device according to an embodiment of the present disclosure;

FIG. 4 is a block diagram showing a configuration of the QED shifter;

FIG. 5A and FIG. 5B are circuit diagrams of the command shifter;

FIG. 6A and FIG. 6B are circuit diagrams of a non-swap path and a swap path;

FIG. 7 shows a generating circuit of control signals controlling non-swap paths and swap paths;

FIG. 8 is a truth table for explaining relations among various control signals;

FIG. 9A to FIG. 9D are waveform diagrams for explaining operations of a non-swap path and a swap path;

FIG. 10 is a circuit diagram of a power save logic; and

FIG. 11 is a circuit diagram of a clock control circuit.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

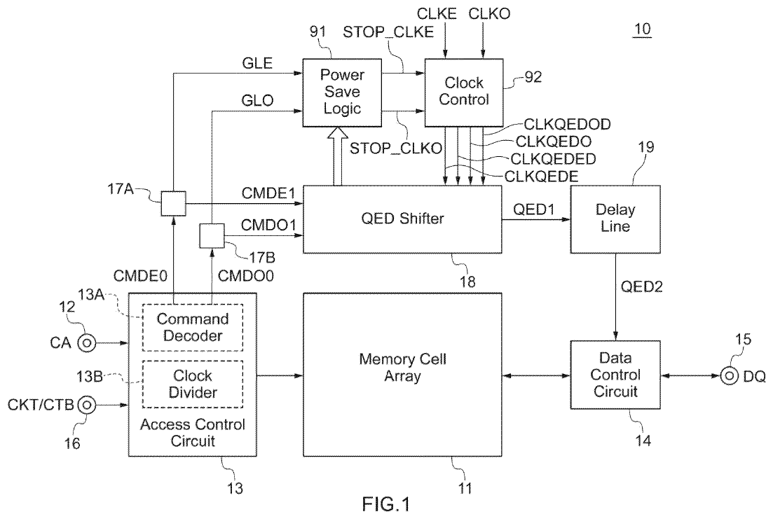

FIG. 1 is a block diagram showing a configuration of a semiconductor device 10 according to an embodiment of the present disclosure. The semiconductor device 10 shown in FIG. 1 is a DDR5 DRAM, for example, and includes a memory cell array 11. When access is made to the memory cell array 11, a command address signal CA is input from outside to a command address terminal 12. The command address signal CA is supplied to an access control circuit 13. The access control circuit 13 includes a command decoder 13A and a clock divider 13B. When an external command included in the command address signal CA indicates a read operation, the access control circuit 13 makes read-access to a memory cell included in the memory cell array 11 based on an address included in the command address signal CA. Read data DQ read from the accessed memory cell is output from a data I/O terminal 15 to outside via a data control circuit 14. When the external command included in the command address signal CA indicates a write operation, write data DQ input from outside to the data I/O terminal 15 is transferred to the memory cell array 11 via the data control circuit 14. The write data DQ having been transferred to the memory cell array 11 is written in the memory cell included in the memory cell array 11 based on the address included in the command address signal CA.

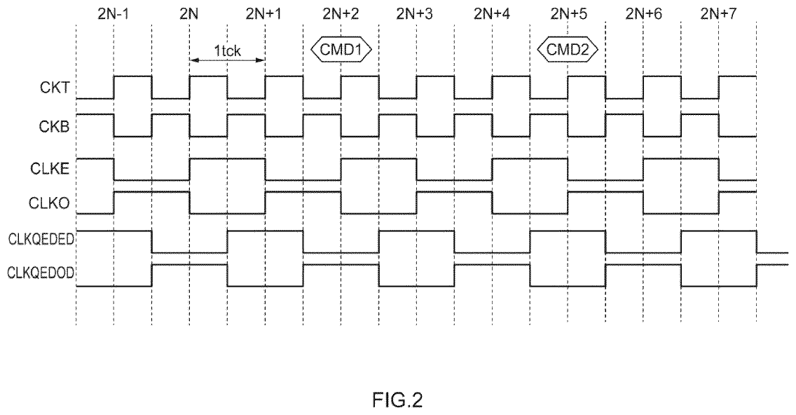

The operation of the access control circuit 13 is performed in synchronization with complementary external clock signals CKT and CKB that are input to a clock terminal 16. The complementary external clock signals CKT and CKB are supplied to the clock driver 13B. The clock divider 13B generates divided clock signals CLKE and CLKO shown in FIG. 2 by dividing the complementary external clock signals CKT and CKB. The divided clock signal CLKE rises in synchronization with even-numbered active edges of the external clock signals CKT and CKB and falls in synchronization with odd-numbered active edges of the external clock signals CKT and CKB. The divided clock signal CLKO rises in synchronization with odd-numbered active edges of the external clock signals CKT and CKB and falls in synchronization with even-numbered active edges of the external clock signals CKT and CKB. That is, the divided clock signals CLKE and CLKO have twice the frequency of the external clock signals CKT and CKB.

As described later, based on the divided clock signals CLKE and CLKO, delayed divided clock signals CLKQEDED and CLKQEDOD are generated inside the semiconductor device 10. The divided clock signal CLKQEDED is generated by, for example, delaying the divided clock signal CLKE and the rising edge thereof is positioned between the rising edge of the divided clock signal CLKE and the rising edge of the divided clock signal CLKO. The divided clock signal CLKQEDOD is generated by, for example, delaying the divided clock signal CLKO and the rising edge thereof is positioned between the rising edge of the divided clock signal CLKO and the rising edge of the divided clock signal CLKE. In the example shown in FIG. 2, the delayed divided clock signals CLKQEDED and CLKQEDOD are delayed by 0.5 tck with respect to the divided clock signals CLKE and CLKO, respectively.

When the external command included in the command address signal CA indicates a read operation, a write operation, a Read non-target operation, or a Write non-target operation, the command decoder 13A included in the access control circuit 13 activates a respective internal command CMDE0 or a respective internal command CMDO0. The internal command CMDE0 is activated when the external command is input in synchronization with even-numbered active edges of the external clock signals CKT and CKB. For example, when a command CMD1 shown in FIG. 2 is input at a timing 2N+2, an internal command CMDE0 is activated. The internal command CMDO0 is activated when the external command is input in synchronization with odd-numbered active edges of the external clock signals CKT and CKB. For example, when a command CMD2 shown in FIG. 2 is input at a timing 2N+5, the internal command CMDO0 is activated.

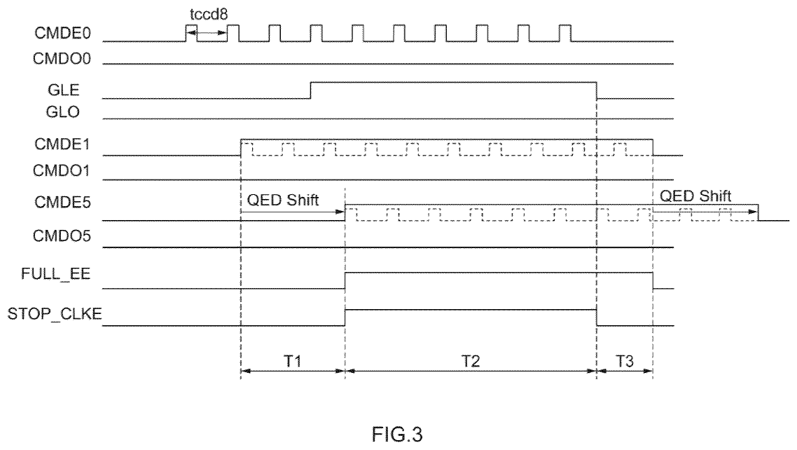

The internal commands CMDE0 and CMDO0 are respectively converted into internal commands CMDE1 and CMDO1 by command extenders 17A and 17B that adjust command widths. The command width of the internal command CMDE1 generated by the command extender 17A is equal to the shortest generation period of the internal command CMDE0 or longer than the shortest generation period. Therefore, when the internal command CMDE0 is generated consecutively at the shortest period, as shown in FIG. 3, the internal command CMDE1 becomes a state where an active level (a high level) is kept. In the example shown in FIG. 3, a shortest generation period tccd of the internal command CMDE0 is eight clock cycles, and when the internal command CMDE0 is generated consecutively at eight clock cycles, the internal command CMDE1 keeps an active level (a high level). Similarly, the command width of the internal command CMDO1 generated by the command extender 17B is equal to the shortest generation period of the internal command CMDO0 or longer than the shortest generation period.

When the internal command CMDE0 is generated consecutively for a predetermined number of times at the shortest period, the command extender 17A activates a determination signal GLE. The determination signal GLE indicates that the active state of a certain internal command CMDE1 and the active state of the subsequent internal command CMDE1 are related to each other and thus these internal commands CMDE1 are keeping an active level for a predetermined period of time. Similarly, when the internal command CMDO0 is generated consecutively for a predetermined number of times at the shortest period, the command extender 17B activates a determination signal GLO. The determination signal GLO indicates that the active state of a certain internal command CMDO1 and the active state of the subsequent internal command CMDO1 are related to each other and thus these internal commands CMDO1 are keeping an active level for a predetermined period of time. In the example shown in FIG. 3, the determination signal GLE is activated in response to a fact that the internal command CMDE0 is generated four times consecutively at the shortest period. The determination signals GLE and GLO are supplied to a power save logic 91. The power save logic 91 generates clock stop signals STOP_CLKE and STOP_CLKO based on the determination signals GLE and GLO and various signals supplied from a QED shifter 18. The clock stop signals STOP_CLKE and STOP_CLKO are supplied to a clock control circuit 92.

The internal commands CMDE1 and CMDO1 are supplied to a QED shifter 18. The QED shifter 18 counts a predetermined latency after the internal commands CMDE1 and CMDO1 are input therein, and then generates an internal command QED1. The internal command QED1 is converted into an internal command QED2 by a delay line 19 that causes a predetermined delay. The internal command QED2 is input to the data control circuit 14. The data control circuit 14 outputs the read data DQ and latches the write data DQ in synchronization with the internal command QED2.

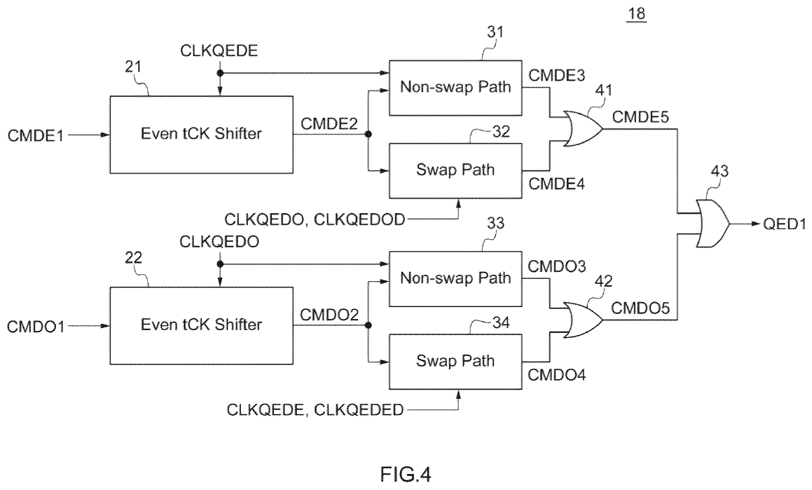

FIG. 4 is a block diagram showing a configuration of the QED shifter 18. As shown in FIG. 4, the QED shifter 18 includes a command shifter 21 that performs a shifting operation on the internal command CMDE1 in synchronization with a divided clock signal CLKQEDE supplied from the clock control circuit 92 and a command shifter 22 that performs a shifting operation on the internal command CMDO1 in synchronization with a divided clock signal CLKQEDO supplied from the clock control circuit 92. As described later, the divided clock signal CLKQEDE is a signal in synchronization with the divided clock signal CLKE and the divided clock signal CLKQEDO is a signal in synchronization with the divided clock signal CLKO.

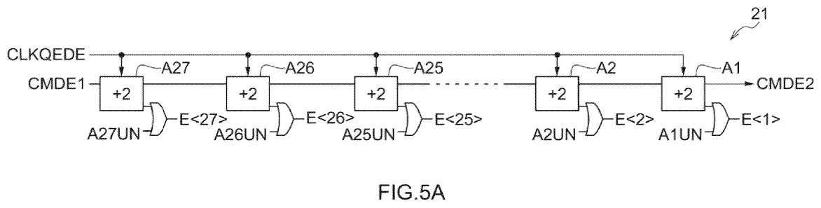

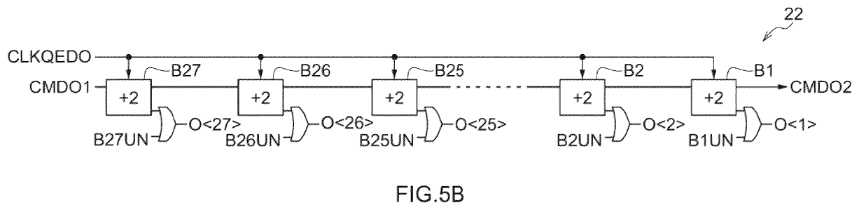

FIG. 5A and FIG. 5B are circuit diagrams of the command shifter 21 and the command shifter 22, respectively. In the example shown in FIG. 5A, the command shifter 21 includes 27 cascade-connected latch circuits A1 to A27. The latch circuits A1 to A27 are bypassed when respectively corresponding control signals A1UN to A27UN are activated to be a high level. When one of or two or more of the latch circuits A1 to A27 are bypassed, these latch circuits are bypassed in order from the first-stage latch circuit A27. Accordingly, a delay equivalent to a maximum of 27 clock cycles of the divided clock signal CLKQEDE with respect to the internal command CMDE0 is caused to the internal command CMDE1. Output signals from the latch circuits A1 to A27 and the controls signals A1UN to A27UN deciding whether or not corresponding latch circuits are bypassed are respectively synthesized with each another by an OR gate circuit, thereby generating determination signals E<1> to E<27>. In the example shown in FIG. 5B, the command shifter 22 includes 27 cascade-connected latch circuits B1 to B27. The latch circuits B1 to B27 are bypassed when respectively corresponding control signals B1UN to B27UN are activated to be a high level. When one of or two or more of the latch circuits B1 to B27 are bypassed, these latch circuits are bypassed in order from the first-stage latch circuit B27. Accordingly, a delay equivalent to a maximum of 27 clock cycles of the divided clock signal CLKQEDO with respect to the internal command CMDO0 is caused to the internal command CMDO1. Output signals from the latch circuits B1 to B27 and the controls signals B1UN to B27UN deciding whether or not corresponding latch circuits are bypassed are respectively synthesized with each another by an OR gate circuit, thereby generating determination signals O<1> to O<27>. The number of times of shifting by the command shifters 21 and 22 is determined by a mode register setting operation or an initializing operation of the delay line 19.

With this configuration, an internal command CMDE2 is delayed only by even-numbered clock cycles with respect to the internal command CMDE1 and an internal command CMDO2 is delayed only by even-numbered clock cycles with respect to the internal command CMDO1. The internal command CMDE2 output from the command shifter 21 is commonly supplied to a non-swap path 31 and a swap path 32. The internal command CMDO2 output from the command shifter 22 is commonly supplied to a non-swap path 33 and a swap path 34.

The non-swap path 31 performs a shifting operation on the internal command CMDE2 in synchronization with the divided clock signal CLKQEDE to generate an internal command CMDE3. With this process, the internal command CMDE3 is delayed only by even-numbered clock cycles with respect to the internal command CMDE2. The swap path 32 performs a shifting operation on the internal command CMDE2 in synchronization with the divided clock signals CLKQEDO and CLKQEDOD to generate an internal command CMDE4. With this process, the internal command CMDE4 is delayed only by odd-numbered clock cycles with respect to the internal command CMDE2. The non-swap path 33 performs a shifting operation on the internal command CMDO2 in synchronization with the divided clock signal CLKQEDO to generate an internal command CMDO3. With this process, the internal command CMDO3 is delayed only by even-numbered clock cycles with respect to the internal command CMDO2. The swap path 34 performs a shifting operation on the internal command CMDO2 in synchronization with the divided clock signals CLKQEDE and CLKQEDED to generate an internal command CMDO4. With this process, the internal command CMDO4 is delayed only by odd-numbered clock cycles with respect to the internal command CMDO2.

The internal commands CMDE3 and CMDE4 are synthesized with each other by an OR gate circuit 41. The internal commands CMDO3 and CMDO4 are synthesized with each other by an OR gate circuit 42. An internal command CMDE5 output from the OR gate circuit 41 and an internal command CMDO5 output from the OR gate circuit 42 are synthesized with each other by an OR gate circuit 43. With this process, the internal command QED1 is generated.

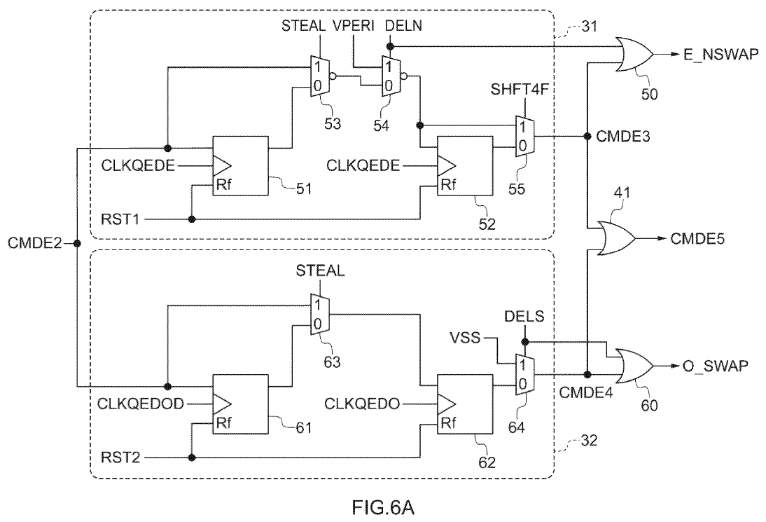

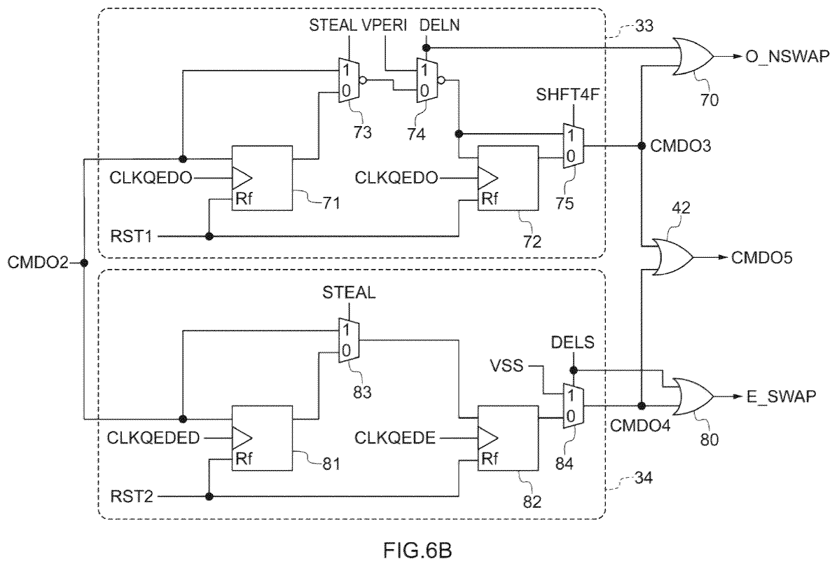

FIG. 6A is a circuit diagram of the non-swap path 31 and the swap path 32. The non-swap path 31 is a circuit that causes a two-clock cycle delay or a four-clock cycle delay to the internal command CMDE2 and includes latch circuits 51 and 52 each of which performs a latch operation in synchronization with the divided clock signal CLKQEDE and multiplexers 53 to 55. The internal command CMDE2 is supplied to an input node of the latch circuit 51. Output of the latch circuit 51 is supplied to an input node of the latch circuit 52 via the multiplexers 53 and 54. Output of the latch circuit 52 is supplied to one input node of the OR gate circuit 41 via the multiplexer 55. The multiplexers 53 to 55 are respectively controlled with control signals STEAL, DELN, and SHFT4F. The latch circuits 51 and 52 are both reset with a reset signal RST1. The swap path 32 is a circuit that causes a three-clock cycle delay to the internal command CMDE2 and includes a latch circuit 61 that performs a latch operation in synchronization with the delayed divided clock signal CLKQEDOD, a latch circuit 62 that performs a latch operation in synchronization with the divided clock signal CLKQEDO, and multiplexers 63 and 64. The internal command CMDE2 is supplied to an input node of the latch circuit 61. Output of the latch circuit 61 is supplied to an input node of the latch circuit 62 via the multiplexer 63. Output of the latch circuit 62 is supplied to the other input node of the OR gate circuit 41 via the multiplexer 64. The multiplexers 63 and 64 are respectively controlled with the control signal STEAL and a control signal DELS. The latch circuits 61 and 62 are both reset with a reset signal RST2.

The control signal DELN and the internal command CMDE3 are supplied to an OR gate circuit 50. Accordingly, a determination signal E_NSWAP output from the OR gate circuit 50 becomes a high level when the non-swap path 31 is in an unused state (DELN=1) or the internal command CMDE3 is in an active state. The control signal DELS and the internal command CMDE4 are supplied to an OR gate circuit 60. Accordingly, a determination signal O_SWAP output from the OR gate circuit 60 becomes a high level when the swap path 32 is in an unused state (DELS=1) or the internal command CMDE4 is in an active state.

FIG. 6B is a circuit diagram of the non-swap path 33 and the swap path 34. The non-swap path 33 is a circuit that causes a two-clock cycle delay or a four-clock cycle delay to the internal command CMDO2 and includes latch circuits 71 and 72 each of which performs a latch operation in synchronization with the divided clock signal CLKQEDO and multiplexers 73 to 75. The internal command CMDO2 is supplied to an input node of the latch circuit 71. Output of the latch circuit 71 is supplied to an input node of the latch circuit 72 via the multiplexers 73 and 74. Output of the latch circuit 72 is supplied to one input node of the OR gate circuit 42 via the multiplexer 75. The multiplexers 73 to 75 are respectively controlled with control signals STEAL, DELN, and SHFT4F. The latch circuits 71 and 72 are both reset with the reset signal RST1. The swap path 34 is a circuit that causes a three-clock cycle delay to the internal command CMDO2 and includes a latch circuit 81 that performs a latch operation in synchronization with the delayed divided clock signal CLKQEDED, a latch circuit 82 that performs a latch operation in synchronization with the divided clock signal CLKQEDE, and multiplexers 83 and 84. The internal command CMDO2 is supplied to an input node of the latch circuit 81. Output of the latch circuit 81 is supplied to an input node of the latch circuit 82 via the multiplexer 83. Output of the latch circuit 82 is supplied to the other input node of the OR gate circuit 42 via the multiplexer 84. The multiplexers 83 and 84 are respectively controlled with the control signals STEAL and DELS. The latch circuits 81 and 82 are both reset with the reset signal RST2.

The control signal DELN and the internal command CMDO3 are supplied to an OR gate circuit 70. Accordingly, a determination signal O_NSWAP output from the OR gate circuit 70 becomes a high level when the non-swap path 33 is in an unused state (DELN=1) or the internal command CMDO3 is in an active state. The control signal DELS and the internal command CMDO4 are supplied to an OR gate circuit 80. Accordingly, a determination signal E_SWAP output from the OR gate circuit 80 becomes a high level when the swap path 34 is in an unused state (DELS=1) or the internal command CMDO4 is in an active state.

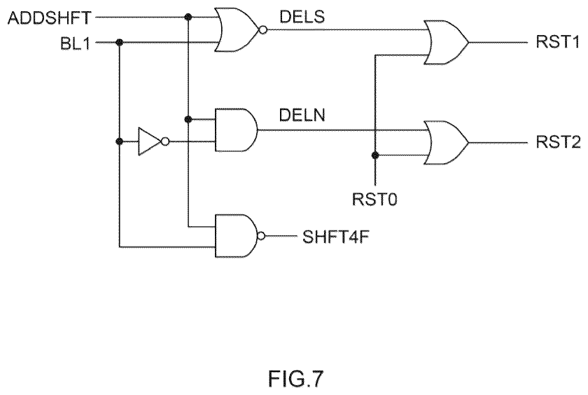

FIG. 7 shows a generating circuit of control signals controlling the non-swap paths 31 and 33 and the swap paths 32 and 34. The circuit shown in FIG. 7 generates the control signals DELS, DELN, SHFT4F, RST1, and RST2 based on control signals ADDSHFT, BL1, and RST0. These control signals are supplied to the non-swap paths 31 and 33 and the swap paths 32 and 34 shown in FIGS. 6A and 6B.

Here, the control signal ADDSHFT is activated when it is necessary to cause an odd-numbered clock cycle delay to the internal command CMDE2 or CMDO2. The control signal BL1 is activated when it is necessary to extend the pulse width of the internal command CMDE2 or CMDO2 by only one clock cycle. The control signal STEAL shown in FIGS. 6A and 6B is normally at a low level (0) and becomes a high level (1) when the shift amount taken by the swap paths 32 and 34 is set to be one clock cycle. That is, when the control signal STEAL is at a high level, the latch circuit 61 included in the swap path 32 is bypassed and the latch circuit 81 included in the swap path 34 is also bypassed. Further, when the control signal STEAL is 1 and the control signal DELN is 0 or the control signal SHFT4F is 1 and the control signal DELN is 0, the shift amount taken by the non-swap paths 31 and 33 becomes two clock cycles. That is, when the control signal STEAL or SHFT4F is at a high level and the control signal DELN is at a low level, the latch circuit 51 or 52 included in the non-swap path 31 is bypassed and the latch circuit 71 or 72 included in the non-swap path 33 is also bypassed.

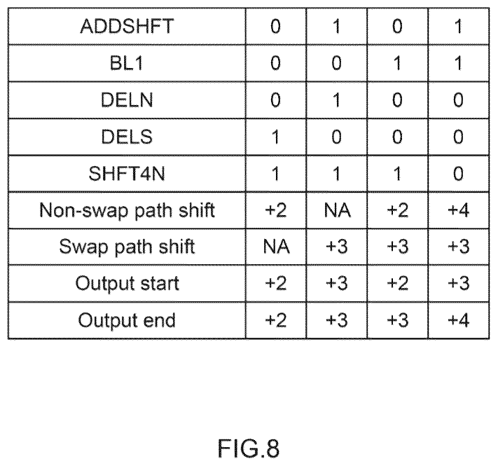

FIG. 8 is a truth table for explaining relations among the control signals ADDSHFT and BL1 and the control signals DELN, DELS, and SHFT4N, and FIG. 8 represents a state where the control signal STEAL is 0.

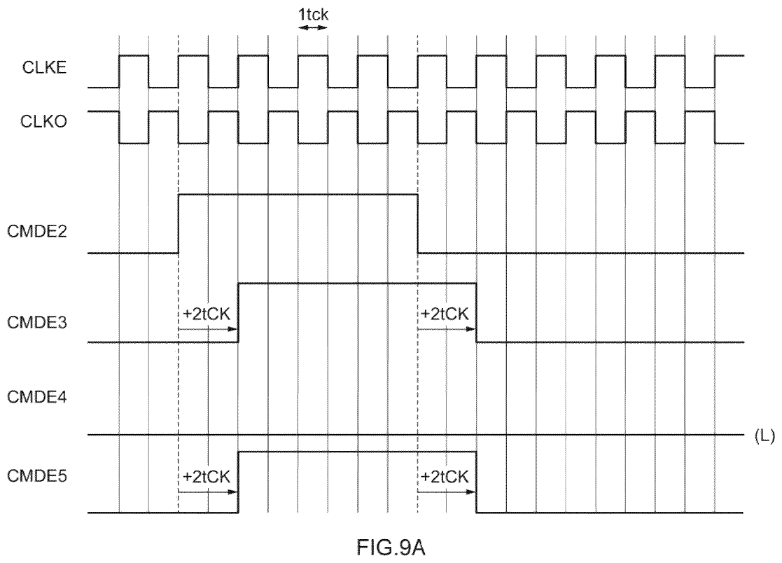

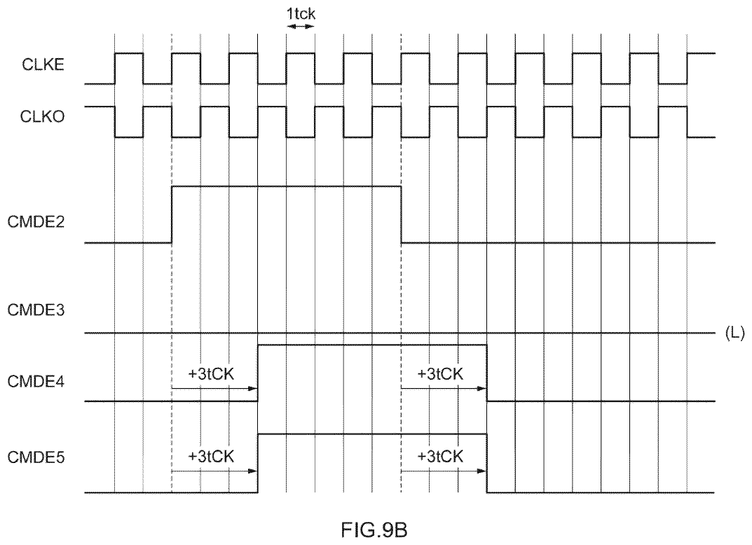

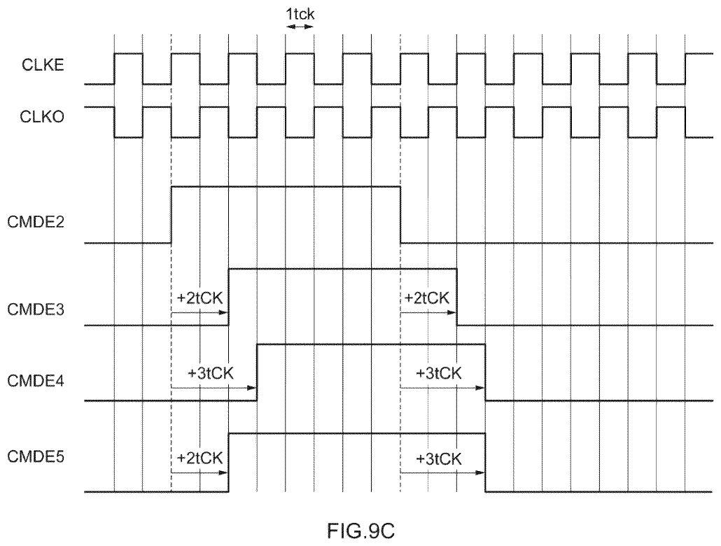

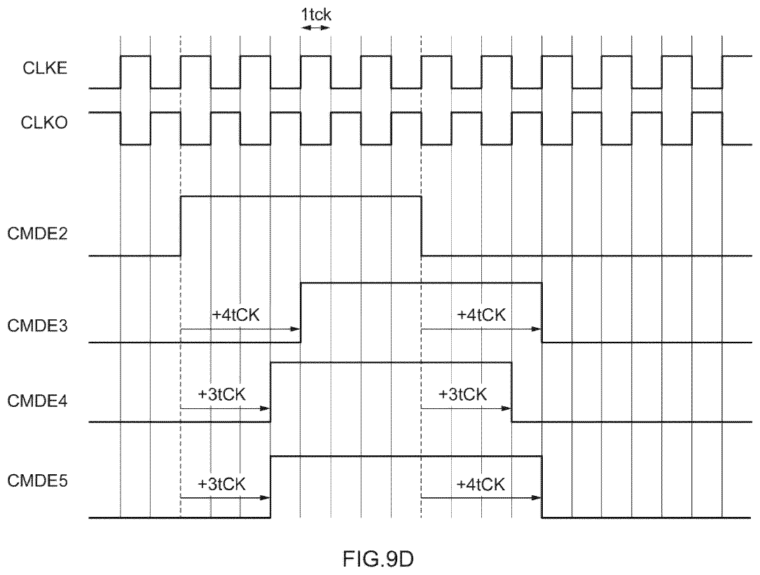

First, in the circuit shown in FIG. 7, when the control signal ADDSHFT is 0 and the control signal BL1 is 0, the control signal DELN is 0, the control signal DELS is 1, and the control signal SHFT4F is 1. Accordingly, the waveforms of the internal commands CMDE2 to CMDE5 are as shown in FIG. 9A, for example. That is, since the latch circuit 52 included in the non-swap path 31 is bypassed in response to the control signal SHFT4F being 1, the non-swap path 31 delays the internal command CMDE2 by two clock cycles using a one-stage latch circuit 51 to generate the internal command CMDE3. Further, since the multiplexer 64 selects to be a low level (=VSS) in response to the control signal DELS being 1, the swap path 32 is disabled and the internal command CMDE4 is fixed to a low level. As a result, as for the internal command CMDE5 output from the OR gate circuit 41, the rising edge and falling edge thereof are delayed by two clock cycles with respect to the internal command CMDE2. That is, the internal command CMDE5 has a pulse width same as that of the internal command CMDE2 and becomes a signal having the internal command CMDE2 delayed by two clock cycles.

In the circuit shown in FIG. 7, when the control signal ADDSHFT is 1 and the control signal BL1 is 0, the control signal DELN is 1, the control signal DELS is 0, and the control signal SHFT4F is 1. Accordingly, the waveforms of the internal commands CMDE2 to CMDE5 are as shown in FIG. 9B, for example. That is, since the multiplexer 54 selects to be a high level (=VPERI) in response to the control signal DELN being 1, the non-swap path 31 is disabled and the internal command CMDE3 is fixed to a low level. Further, the swap path 32 has a state where two-stage latch circuits 61 and 62 are coupled to each other in series. Here, since the last-stage latch circuit 62 performs a latch operation in synchronization with the divided clock signal CLKQEDO, the swap path 32 delays the internal command CMDE2 by three clock cycles to generate the internal command CMDE4. As a result, as for the internal command CMDE5 output from the OR gate circuit 41, the rising edge and falling edge thereof are delayed by three clock cycles with respect to the internal command CMDE2. That is, the internal command CMDE5 has a pulse width same as that of the internal command CMDE2 and becomes a signal having the internal command CMDE2 delayed by three clock cycles. Further, since the first-stage latch circuit 61 performs a latch operation in synchronization with the delayed divided clock signal CLKQEDOD, latch margins at the first-stage latch circuits 61 and 62 are also increased. For example, the latch margins at the latch circuits 61 and 62 are both 1.5 tCK.

In the circuit shown in FIG. 7, when the control signal ADDSHFT is 0 and the control signal BL1 is 1, the control signal DELN is 0, the control signal DELS is 0, and the control signal SHFT4F is 1. Accordingly, the waveforms of the internal commands CMDE2 to CMDE5 are as shown in FIG. 9C, for example. That is, since the latch circuit 52 included in the non-swap path 31 is bypassed in response to the control signal SHFT4F being 1, the non-swap path 31 delays the internal command CMDE2 by two clock cycles using the one-stage latch circuit 51 to generate the internal command CMDE3. Further, the swap path 32 has a state where the two-stage latch circuits 61 and 62 are coupled to each other in series. As a result, as for the internal command CMDE5 output from the OR gate circuit 41, the rising edge thereof is delayed by two clock cycles with respect to the internal command CMDE2 and the falling edge thereof is delayed by three clock cycles with respect to the internal command CMDE2. That is, the internal command CMDE5 has a pulse width extended by one clock cycle as compared to that of the internal command CMDE2 and becomes a signal having the internal command CMDE2 delayed by two clock cycles.

In the circuit shown in FIG. 7, when the control signal ADDSHFT is 1 and the control signal BL1 is 1, the control signal DELN is 0, the control signal DELS is 0, and the control signal SHFT4F is 0. Accordingly, the waveforms of the internal commands CMDE2 to CMDE5 are as shown in FIG. 9D, for example. That is, since the non-swap path 31 has a state where two-stage latch circuits 51 and 52 are coupled to each other in series, the non-swap path 31 delays the internal command CMDE2 by four clock cycles using the two-stage latch circuits 51 and 52 to generate the internal command CMDE3. Further, the swap path 32 has a state where the two-stage latch circuits 61 and 62 are coupled to each other in series. As a result, as for the internal command CMDE5 output from the OR gate circuit 41, the rising edge thereof is delayed by three clock cycles with respect to the internal command CMDE2 and the falling edge thereof is delayed by four clock cycles with respect to the internal command CMDE2. That is, the internal command CMDE5 has a pulse width extended by one clock cycle as compared to that of the internal command CMDE2 and becomes a signal having the internal command CMDE2 delayed by three clock cycles.

The operations of the non-swap path 31 and the swap path 32 described above with reference to FIGS. 9A to 9D are also applied to the non-swap path 33 and the swap path 34. Further, the internal command CMDE5 generated by passing through the non-swap path 31 and the swap path 32 and the internal command CMDO5 generated by passing through the non-swap path 33 and the swap path 34 are synthesized with each other by the OR gate circuit 43 shown in FIG. 4, thereby generating the internal command QED1.

As described above, in the semiconductor device according to the present disclosure, the non-swap path 31 causing an even-numbered clock cycle delay to the internal command CMDE2 and the swap path 32 causing an odd-numbered clock cycle delay to the internal command CMDE2 are coupled to each other in parallel and the internal command CMDE3 output from the non-swap path 31 and the internal command CMDE4 output from the swap path 32 are synthesized with each other, so that it is possible to cause an odd-numbered clock cycle delay to the internal command CMDE1 while securing a sufficient operation margin. Similarly, the non-swap path 33 causing an even-numbered clock cycle delay to the internal command CMDO2 and the swap path 34 causing an odd-numbered clock cycle delay to the internal command CMDO2 are coupled to each other in parallel and the internal command CMDO3 output from the non-swap path 33 and the internal command CMDO4 output from the swap path 34 are synthesized with each other, so that it is possible to cause an odd-numbered clock cycle delay to the internal command CMDO1 while securing a sufficient operation margin.

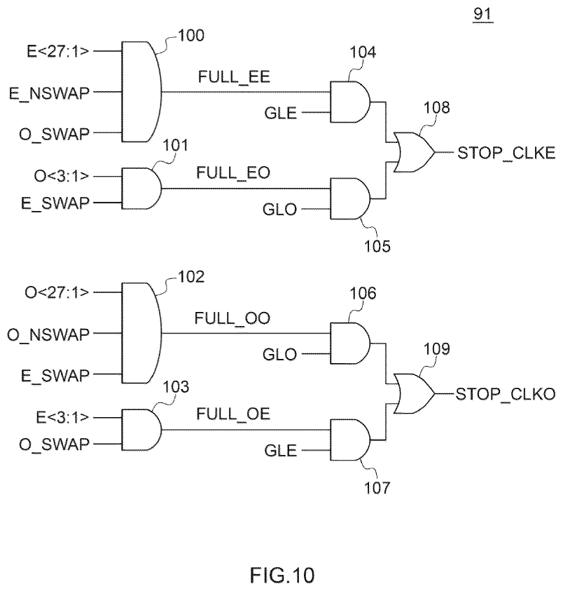

FIG. 10 is a circuit diagram of the power save logic 91. As shown in FIG. 10, the power save logic 91 includes an AND gate circuit 100 that receives a determination signal E<27:1>, the determination signal E_NSWAP, and the determination signal O_SWAP, an AND gate circuit 101 that receives a determination signal O<3:1> and the determination signal E_SWAP, an AND gate circuit 102 that receives a determination signal O<27:1>, the determination signal O_NSWAP, and the determination signal E_SWAP, and an AND gate circuit 103 that receives a determination signal E<3:1> and the determination signal O_SWAP.

A determination signal FULL_EE output from the AND gate circuit 100 indicates that the internal commands CMDE1 to CMDE3 on which a shifting operation is performed using the divided clock signal CLKE are keeping an active level. That is, the determination signal FULL_EE is activated when the internal command CMDE1 is set in all the enabled (not bypassed) latch circuits included in the command shifter 21 and the internal command CMDE3 output from the non-swap path 31 is at an active level. As described above with reference to FIG. 9A, when the swap path 32 is disabled, the determination signal O_SWAP is fixed to a high level. The determination signal O_SWAP originated from the internal command CMDO1 is input to the AND gate circuit 100 in order to reduce the pulse width of the determination signal FULL_EE when the non-swap path 31 is bypassed and only the swap path 32 is used. When both the determination signal FULL_EE and the determination signal GLE are activated, the clock stop signal STOP_CLKE is activated by an AND gate circuit 104 and an OR gate circuit 108.

A determination signal FULL_EO output from the AND gate circuit 101 indicates that the internal command CMDO4 on which a shifting operation is performed using the divided clock signal CLKE is keeping an active level. That is, the determination signal FULL_EO indicates that all the shifters not bypassed are keeping an active level when the internal command CMDO1 originally in synchronization with the divided clock signal CLKO is shifted using the divided clock signal CLKE. The determination signal O<3:1> originated from the divided clock signal CLKO is input to the AND gate circuit 101 in order to reduce the pulse width of the determination signal FULL_EO on a condition that the internal command CMDO1 is latched in last three latch circuits B1 to B3 included in the command shifter 22. When both the determination signal FULL_EO and the determination signal GLO (both are originated from the internal command CMDO1) are activated, the clock stop signal STOP_CLKE is activated by an AND gate circuit 105 and the OR gate circuit 108.

A determination signal FULL_OO output from the AND gate circuit 102 indicates that the internal commands CMDO1 to CMDO3 on which a shifting operation is performed using the divided clock signal CLKO are keeping an active level. That is, the determination signal FULL_OO is activated when the internal command CMDO1 is set in all the enabled (not bypassed) latch circuits included in the command shifter 22 and the internal command CMDO3 output from the non-swap path 33 is at an active level. When the swap path 34 is disabled, the determination signal E_SWAP is fixed to a high level. The determination signal E_SWAP originated from the internal command CMDE1 is input to the AND gate circuit 102 in order to reduce the pulse width of the determination signal FULL_OO when the non-swap path 33 is bypassed and only the swap path 34 is used. When both the determination signal FULL_OO and the determination signal GLO are activated, the clock stop signal STOP_CLKO is activated by an AND gate circuit 106 and an OR gate circuit 109.

A determination signal FULL_OE output from the AND gate circuit 103 indicates that the internal command CMDE4 on which a shifting operation is performed using the divided clock signal CLKO is keeping an active level. That is, the determination signal FULL_OE indicates that all the shifters not bypassed are keeping an active level when the internal command CMDE1 originally in synchronization with the divided clock signal CLKE is shifted using the divided clock signal CLKO. The determination signal E<3:1> originated from the divided clock signal CLKE is input to the AND gate circuit 103 in order to reduce the pulse width of the determination signal FULL_OE on a condition that the internal command CMDE1 is latched in last three latch circuits A1 to A3 included in the command shifter 21. When both the determination signal FULL_OE and the determination signal GLE (both are originated from the internal command CMDE1) are activated, the clock stop signal STOP_CLKO is activated by an AND gate circuit 107 and the OR gate circuit 109.

The clock stop signals STOP_CLKE and STOP_CLKO are supplied to the clock control circuit 92 as shown in FIG. 1.

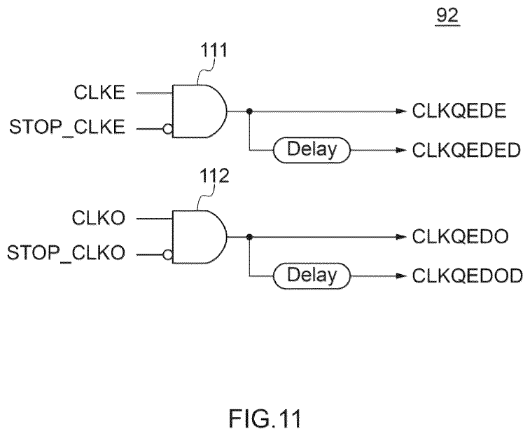

FIG. 11 is a circuit diagram of the clock control circuit 92. As shown in FIG. 11, the clock control circuit 92 includes an AND gate circuit 111 that receives the divided clock signal CLKE and (an inverted signal of) the clock stop signal STOP_CLKE and an AND gate circuit 112 that receives the divided clock signal CLKO and (an inverted signal of) the clock stop signal STOP_CLKO. Accordingly, when the clock stop signal STOP_CLKE is activated to be a high level, clocking of the divided clock signal CLKQEDE is stopped, and when the clock stop signal STOP_CLKO is activated to be a high level, clocking of the divided clock signal CLKQEDO is stopped. Further, when the clock stop signal STOP_CLKE is activated to be a high level, the divided clock signal CLKQEDED generated by delaying the divided clock signal CLKQEDE is also stopped. Similarly, when the clock stop signal STOP_CLKO is activated to be a high level, the divided clock signal CLKQEDOD generated by delaying the divided clock signal CLKQEDO is also stopped.

Accordingly, since the internal commands CMDE1 to CMDE3 are keeping an active level, when any shifting operation by the command shifter 21 and the non-swap path 31 using the divided clock signal CLKQEDE is not necessary or when the latch circuits A1 to A27, 51, 52, 81, and 82 using the divided clock signal CLKQEDE are unused, the divided clock signal CLKQEDE is stopped. Similarly, since the internal commands CMDO1 to CMDO3 are keeping an active level, when any shifting operation by the command shifter 22 and the non-swap path 33 using the divided clock signal CLKQEDO is not necessary or when the latch circuits B1 to B27, 61, 62, 71, and 72 using the divided clock signal CLKQEDO are unused, the divided clock signal CLKQEDO is stopped. As a result, the consumption current due to unnecessary clocking of the divided clock signals CLKQEDE and CLKQEDO can be reduced.

As described above, in the semiconductor device according to the present disclosure, the necessity of the divided clock signals CLKQEDE and CLKQEDO is determined individually, and when it is determined to be unnecessary, clocking of the divided clock signal CLKQEDE or the divided clock signal CLKQEDO is stopped individually. Therefore, reduction of consumption current can be made efficiently regardless of the configurations of shifters and command input patterns. As AND synthesis is performed between the determination signal GLE originated from the internal command CMDE1 and the determination signals FULL_EE and FULL_OE as well as the determination signal GLO originated from the internal command CMDO1 and the determination signals FULL_EO and FULL_OO respectively and individually, when an internal command CLKO1 is input right after inputting an internal command CLKE1 or vice versa, commands can be shifted correctly while reducing current consumption. Further, by using the clock stop signals STOP_CLKE and STOP_CLKO respectively and individually with respect to the divided clock signals CLKE and CLKO, even when used clock signals are switched or commands are processed in parallel due to the configurations of shifters, commands can be shifted correctly while reducing current consumption. For example, in the example shown in FIG. 3, in the time period T2 where both the determination signal GLE and the determination signal FULL_EE are activated, the clock stop signal STOP_CLKE is activated. Accordingly, during a time period where the internal command CMDE1 keeps an active state, in the time period T2 excluding the first time period T1 and the last time period T3, clocking of the divided clock signal CLKQEDE can be stopped. In this manner, even when the internal command CMDE1 is keeping an active state, clocking of the divided clock signal CLKQEDE is correctly performed in the first time period T1 and the last time period T3, so that rise (transition from an inactivated state to an active state) of the internal command CMDE1 and fall (transition from an active state to an inactive state) of the internal command CMDE1 can be controlled correctly.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a command decoder configured to generate a first even internal command responsive to an external command received at an even clock cycle and a first odd internal command responsive to an external command received at an odd clock cycle;
an even global command path coupled to the command decoder and configured to drive the first even internal command responsive, at least in part, to a first clock signal, the even global command path including a first command extender configured to extend a pulse width of the first even internal command to generate a second even internal command, the first command extender configured to activate a first detection signal when the second even internal command keeps an active state during a predetermined period of time;
an odd global command path coupled to the command decoder and configured to drive the first odd internal command responsive, at least in part, to a second clock signal, the odd global command path including a second command extender configured to extend a pulse width of the first odd internal command to generate a second odd internal command, the second command extender configured to activate a second detection signal when the second odd internal command keeps an active state during a predetermined period of time; and
a clock control circuit configured to control whether or not the first clock signal is provided to at least a portion of the even global command path based, at least in part, on the first detection signal and control whether or not the second clock signal is provided to at least a portion of the odd global command path based, at least in part, on the second detection signal.

2. The apparatus of claim 1,
wherein the clock control circuit is configured to stop providing the first clock signal to at least a portion of the even global command path regardless of whether or not the second clock signal is provided to at least a portion of the odd global command path, and
wherein the clock control circuit is configured to stop providing the second clock signal to at least a portion of the odd global command path regardless of whether or not the first clock signal is provided to at least a portion of the even global command path.

3. The apparatus of claim 2,
wherein the even global command path further includes a first command shifter including a plurality of first latch circuits operatively coupled in series and configured to shift the second even internal command to generate a third even internal command responsive to the first clock signal,
wherein the first command shifter is configured to activate a third detection signal when each of the plurality of first latch circuits operatively coupled in series latches the second even internal command, and
wherein the clock control circuit is configured to control whether or not the first clock signal is provided to the first command shifter based, at least in part, on the first and third detection signals.

4. The apparatus of claim 3,
wherein the even global command path further includes:
a first even local path coupled to the first command shifter and configured to generate a fourth even internal command responsive to the first clock signal;
a second even local path coupled to the first command shifter and configured to generate a fifth even internal command responsive to the second clock signal; and
a first gate circuit coupled to the first and second even local paths and configured to generate a sixth even internal command based on the fourth even internal command and the fifth even internal command, and
wherein the clock control circuit is configured to stop providing the first clock signal to the first command shifter and the first even local path when the first detection signal, the third detection signal, the fourth even internal command, and the fifth even internal command are activated.

5. The apparatus of claim 4,
wherein the first even local path is configured to be disabled when a first control signal is activated, and
wherein the clock control circuit is configured to stop providing the first clock signal to the first command shifter and the first even local path when the first detection signal, the third detection signal, the first control signal, and the fifth even internal command are activated.

6. The apparatus of claim 5,
wherein the second even local path is configured to be disabled when a second control signal is activated, and
wherein the clock control circuit is configured to stop providing the first clock signal to the first command shifter and the first even local path when the first detection signal, the third detection signal, the second control signal, and the fourth even internal command are activated.

7. The apparatus of claim 6, wherein the clock control circuit is configured to stop providing the second clock signal to the second even local path when the first detection signal and the second control signal are activated.

8. The apparatus of claim 3,
wherein the odd global command path further includes a second command shifter including a plurality of second latch circuits operatively coupled in series and configured to shift the second odd internal command to generate a third odd internal command responsive to the second clock signal,
wherein the second command shifter is configured to activate a fourth detection signal when each of the plurality of second latch circuits operatively coupled in series latches the second odd internal command, and
wherein the clock control circuit is configured to control whether or not the second clock signal is provided to the second command shifter based, at least in part, on the second and fourth detection signals.

9. The apparatus of claim 8,
wherein the odd global command path further includes:
a first odd local path coupled to the second command shifter and configured to generate a fourth odd internal command responsive to the second clock signal;
a second odd local path coupled to the second command shifter and configured to generate a fifth odd internal command responsive to the first clock signal; and
a second gate circuit coupled to the first and second odd local paths and configured to generate a sixth odd internal command based on the fourth odd internal command and the fifth odd internal command, and
wherein the clock control circuit is configured to stop providing the second clock signal to the second command shifter and the first odd local path when the second detection signal and the fourth detection signal, the fourth odd internal command, and the fifth odd internal command are activated.

10. The apparatus of claim 9,
wherein the first odd local path is configured to be disabled when a first control signal is activated, and
wherein the clock control circuit is configured to stop providing the second clock signal to the second command shifter and the first odd local path when the second detection signal, the fourth detection signal, the first control signal, and the fifth odd internal command are activated.

11. The apparatus of claim 10,
wherein the second odd local path is configured to be disabled when a second control signal is activated, and
wherein the clock control circuit is configured to stop providing the second clock signal to the second command shifter and the first odd local path when the second detection signal, the fourth detection signal, the second control signal, and the fourth odd internal command are activated.

12. The apparatus of claim 11, wherein the clock control circuit is configured to stop providing the first clock signal to the first command shifter and the second odd local path when the second detection signal and the second control signal are activated.

13. The apparatus of claim 1, wherein the second clock signal has an opposite phase to the first clock signal.

14. The apparatus of claim 1,
wherein the first command extender is configured to generate the second even internal command by extending a pulse width of the first even internal command from first clock cycles to second clock cycles or more,
wherein the second command extender is configured to generate the second odd internal command by extending a pulse width of the first odd internal command from the first clock cycles to the second clock cycles or more,
wherein the second even internal command keeps an active state when a plurality of the first even internal commands are successively issued in the second clock cycles, and
wherein the second odd internal command keeps an active state when a plurality of the first odd internal commands are successively issued in the second clock cycles.

15. An apparatus comprising:
a first command extender configured to extend a pulse width of a first command from first clock cycles to second clock cycles or more to generate a second command;
a second command extender configured to extend a pulse width of a third command rom the first clock cycles to the second clock cycles or more to generate a fourth command;
a first command shifter configured to shift the second command to generate a fifth command responsive to a first clock signal;
a second command shifter configured to shift the fourth command to generate a sixth command responsive to a second clock signal; and
a clock control circuit configured to stop providing the first clock signal to the first command shifter regardless of whether or not the second clock signal is provided to the second command shifter and stop providing the second clock signal to the second command shifter regardless of whether or not the first clock signal is provided to the first command shifter.

16. The apparatus of claim 15,
wherein the first command extender is configured to activate a first detection signal when the second command keeps an active state during a predetermined period of time,
wherein the second command extender is configured to activate a second detection signal when the fourth command keeps an active state during a predetermined period of time,
wherein the clock control circuit is configured to stop providing the first clock signal to the first command shifter based, at least in part, on the first detection signal, and
wherein the clock control circuit is configured to stop providing the second clock signal to the second command shifter based, at least in part, on the second detection signal.

17. The apparatus of claim 16,
wherein the first command shifter includes a plurality of first latch circuits operatively coupled in series and configured to shift the second command to generate the fifth command responsive to the first clock signal,
wherein the second command shifter includes a plurality of second latch circuits operatively coupled in series and configured to shift the fourth command to generate the sixth command responsive to the second clock signal,
wherein the first command shifter is configured to activate a third detection signal when each of the plurality of first latch circuits operatively coupled in series latches the second command,
wherein the second command shifter is configured to activate a fourth detection signal when each of the plurality of second latch circuits operatively coupled in series latches the fourth command,
wherein the clock control circuit is configured to stop providing the first clock signal to the first command shifter based, at least in part, on the third detection signal, and
wherein the clock control circuit is configured to stop providing the second clock signal to the second command shifter based, at least in part, on the fourth detection signal.

18. The apparatus of claim 15, wherein the second clock signal has an opposite phase to the first clock signal.

19. The apparatus of claim 18, further comprising:
an external terminal electrode configured to receive an external command; and
a command decoder configured to decode the external command responsive to a third clock signal having twice a frequency of the first and second clock signals,
wherein the command decoder is configured to:
generate the first command when the external command is received in synchronization with an even-numbered edge of the third clock signal; and
generate the third command when the external command is received in synchronization with an odd-numbered edge of the third clock signal.

20. An apparatus comprising:
a clock divider configured to divide an original clock signal to generate first and second divided clock signals having opposite phases to each other;
a first command extender configured to extend a pulse width of a first command to generate a second command;
a second command extender configured to extend a pulse width of a third command to generate a fourth command;
a first command shifter configured to shift the second command responsive to the first divided clock signal to generate a fifth command, wherein a delay amount of the fifth command from the second command is even-numbered clock cycles of the original clock signal;
a second command shifter configured to shift the fourth command responsive to the second divided clock signal to generate a sixth command, wherein a delay amount of the sixth command from the fourth command is even-numbered clock cycles of the original clock signal; and
a clock control circuit configured to stop providing the first divided clock signal to the first command shifter regardless of whether or not the second divided clock signal is provided to the second command shifter and stop providing the second divided clock signal to the second command shifter regardless of whether or not the first divided clock signal is provided to the first command shifter.
